(19) United States
(12) Patent Application Publication
(10) Pub. No.: US 2026/0059821 A1
(43) Pub. Date: Feb. 26, 2026

(54) SELF-PATTERNING ELECTRODE AND ITS MANUFACTURING METHOD

(71) Applicant: University-Industry Cooperation Group of Kyung Hee University, Yongin-Si (KR)

(72) Inventor: Woojin Jeon, Hwaseong-Si (KR)

(73) Assignee: University-Industry Cooperation Group of Kyung Hee University, Yongin-Si (KR)

(21) Appl. No.: 19/070,823

(22) Filed: Mar. 5, 2025

(30) Foreign Application Priority Data
Aug. 21, 2024 (KR) 10-2024-0112140

(51) Int. Cl. H10D 64/01; H10D 64/68

(52) U.S. Cl. CPC H10D 64/01; H10D 64/691; H10D 64/693

(57) ABSTRACT

A method for manufacturing a self-patterning electrode includes preparing a substrate patterned with a metal nitride; forming a molybdenum oxide layer on the patterned substrate; and heat-treating the substrate on which the molybdenum oxide layer is formed, and a self-patterning electrode manufactured using the method.

### CROSS-REFERENCE TO RELATED APPLICATION

This application claims the benefit under 35 U.S.C. § 119(a) of Korean Patent Application No. 10-2024-0112140, filed on Aug. 21, 2024, the entire disclosure of which is incorporated herein by reference for all purposes.

### BACKGROUND

### 1. Field

The present disclosure relates to a self-patterning electrode and a method for manufacturing the same, and in particular to a method for manufacturing a self-patterning electrode that eliminates the need for complex processes such as exposure and etching, and a self-patterning electrode manufactured by the method.

Meanwhile, the present invention is a result of research conducted with the support of the Center for Next-Generation Semiconductors project of the Gyeonggi-do Regional Research Center (research project title: Development of Functional Thin Film Micro-Control Processes for Memory and Next-Generation Semiconductor Devices, Project Number: GRRCKyungHee2023-B02).

### 2. Description of Related Art

In the entire history of the semiconductor device development, patterning process development has always been the most important challenging issue to demonstrate the next-generation semiconductor device through the design-rule shrinkage. However, the increasing difficulty in patterning processes based on the lithography technology for design rules at 1x−nm and beyond has disrupted the traditional semiconductor development paradigm, which aimed to ensure cost-effectiveness through chip size reduction.

The patterning process in the semiconductor industry may be generally described as a series of steps in which a material, such as a metal, an insulator, or a semiconductor, is deposited over the entire surface of a substrate, followed by lithography and etching to leave the material only in desired regions, thereby forming structures that are separated from one another. In this regard, various innovative breakthrough technologies for the patterning process to reduce dependency on lithography have emerged, such as vertical integration, area-selective deposition, and atomic layer etching processes. However, these alternative processes are not yet mature enough to be adopted.

### SUMMARY

The present invention has been devised to address the aforementioned issues and discloses a method for manufacturing a self-patterning electrode, enabling simpler electrode film patterning by controlling the oxidation number of molybdenum oxide through a metal nitride.

In one general aspect, a method for manufacturing a self-patterning electrode includes preparing a substrate patterned with a metal nitride; forming a molybdenum oxide layer on the patterned substrate; and heat treating the substrate on which the molybdenum oxide layer is formed.

The metal nitride may exhibit a rutile crystal phase as it undergoes oxidation.

The metal nitride may include one or more substances selected from a group consisting of TiN, SnN and RuN.

The molybdenum oxide layer may be formed using a molybdenum precursor and an oxidant.

The molybdenum precursor may be one or more substances selected from a group consisting of Mo(CO)₆, MoO₂Cl₂, MoF₆, (tBuN)₂Mo(NMe₂)₂, and (tBuN)₂Mo(Net₂)₂.

The oxidant may be one or more selected from a group consisting of O₃, H₂O, and O₂ plasmas.

The heat treatment may be performed at a temperature ranging from 400 to 700° C.

The molybdenum oxide layer may be converted into molybdenum oxides having different oxidation numbers as heat treatment is performed on the substrate.

In portions of the substrate patterned with the metal nitride, MoO₂ may be formed, and in portions of the substrate not patterned with the metal nitride, MoO₃ may be formed.

In another general aspect, to achieve the aforementioned objective, a self-patterning electrode manufactured by the method described above is disclosed.

The method for manufacturing a self-patterning electrode of the present invention enables the easy formation of conductive MoO₂ and insulating MoO₃ by isolating them without the need for complex processes such as lithography and etching.

### BRIEF DESCRIPTION OF THE DRAWINGS

FIG. 1 is a flowchart illustrating a manufacturing process of a self-patterning electrode according to the present disclosure.

FIG. 2 is a schematic diagram illustrating the oxidation number of molybdenum oxide based on the heat treatment temperature and type of substrate of a self-patterning electrode according to the present disclosure.

FIG. 3 is a schematic diagram illustrating a manufacturing process of a self-patterning electrode according to an example of the present disclosure.

FIG. 4 is a schematic diagram illustrating the crystal structure of a self-patterning electrode according to the present disclosure.

FIG. 5 is an XRD spectrum of a self-patterning electrode manufactured according to an example of the present disclosure.

FIG. 6 is a graph illustrating the composition ratio of molybdenum ion oxidation numbers according to the heat treatment temperature and type of substrate of a self-patterning electrode manufactured according to an example of the present disclosure.

FIG. 7 is a graph illustrating the resistance of a self-patterning electrode manufactured according to an example of the present disclosure.

FIG. 8 illustrates HR-TEM images, FFT images, EELS analyses, and a resistance graph of a self-patterning electrode manufactured according to an example of the present disclosure.

FIG. 9 illustrates HR-TEM images of a self-patterning electrode manufactured according to an example of the present disclosure.

FIG. 10 illustrates an HR-TEM image and an FFT image of a self-patterning electrode manufactured according to an example of the present disclosure.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

A detailed description is given below, with reference to attached drawings.

The present disclosure describes a method for manufacturing a self-patterning electrode as a means of achieving the above-mentioned objectives.

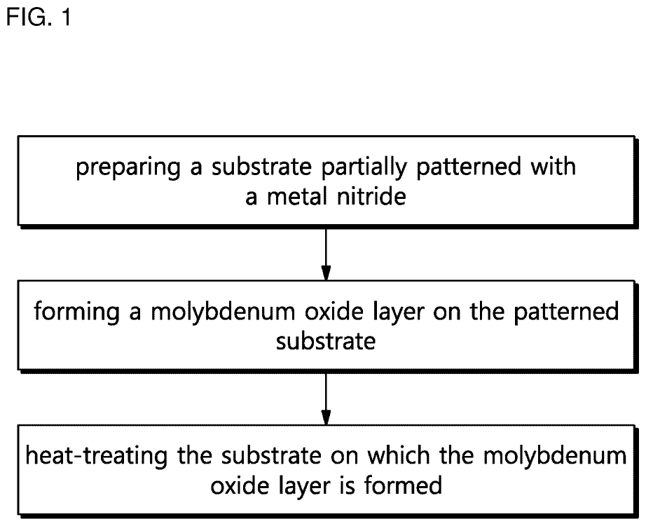

FIG. 1 is a flowchart illustrating a manufacturing process of a self-patterning electrode according to the present disclosure. Referring to FIG. 1, it can be confirmed that a method for manufacturing a self-patterning electrode according to the present disclosure includes preparing a substrate patterned with a metal nitride; forming a molybdenum oxide layer on the patterned substrate; and heat treating the substrate on which the molybdenum oxide layer is formed.

Hereinafter, the manufacturing method of the self-patterning electrode according to the present disclosure will be described in more detail, step-by-step.

The manufacturing method of the present disclosure first includes preparing a substrate patterned with a metal nitride.

The method of patterning the metal nitride on the substrate may be any method known in the art, and according to an example of the present disclosure, the metal nitride may be deposited on an entire surface of the substrate using chemical vapor deposition and then patterned using lithography and etching processes.

Herein, the metal nitride may exhibit a rutile crystal structure as it undergoes oxidation. The rutile structure refers to a configuration in which the central element forms a tetragonal body-centered unit cell, with oxygen atoms surrounding the central element in an octahedral arrangement. The octahedron formed by the oxygen atoms is slightly distorted.

The oxidized metal nitride, exhibiting a rutile structure, may change the crystal structure of the molybdenum oxide layer formed later on the metal nitride through a template effect.

To summarize, in the present disclosure, a substrate including a portion where the metal nitride is formed (patterned) and a portion where the metal nitride is not formed is first prepared. Then, when a molybdenum oxide layer is formed on the prepared substrate by the steps described hereinafter and heat treated, the molybdenum oxide layer formed on the metal nitride is reduced by reaction with the metal nitride due to the difference in oxygen affinity, resulting in formation of MoO₂. Through the template effect of the oxidized metal nitride (rutile structure), the MoO₂ may be crystallized into a monoclinic crystal structure. On the other hand, the molybdenum oxide formed on the portion where the metal nitride is not formed may be formed as MoO₃, its most stable form among the various oxidation states of molybdenum oxides.

The metal nitride described herein may include one or more substances selected from a group consisting of TiN, SnN, and RuN, but is not limited thereto. As described above, any metal nitride that has a higher oxygen affinity than molybdenum and whose oxidized final form exhibits a rutile structure is suitable.

Next, the manufacturing method according to the present disclosure includes forming a molybdenum oxide layer on the patterned substrate.

Herein, the molybdenum oxide layer may be formed using a molybdenum precursor and an oxidant. The molybdenum oxide layer may be formed by known methods, and according to an example of the present disclosure, it may be formed using atomic layer deposition.

Herein, the molybdenum precursor may be one or more substances selected from a group consisting of Mo(CO)₆, MoO₂Cl₂, MoF₆, (tBuN)₂Mo(NMe₂)₂, and (tBuN)₂Mo(NEt₂)₂, but is not limited thereto.

Herein, the oxidant may be one or more substances selected from a group consisting of O₃, H₂O, and O₂ plasma, but is not limited thereto.

In addition, to maintain conductivity in the molybdenum oxide layer formed on the metal nitride, it is preferable that the layer be formed with a thickness of 15 nm or less. If the thickness of the molybdenum oxide layer exceeds 15 nm, there may be a portion where the template effect of the metal nitride is not affected, resulting in capping of the insulating MoO₃ on the conductive MoO₂. However, paradoxically, if capping an insulator on a conductor is required, forming the molybdenum oxide layer with a thickness exceeding 15 nm may make capping of the insulator on the conductor an easier process.

Next, the manufacturing method according to the present disclosure includes heat-treating the substrate on which the molybdenum oxide layer is formed.

The molybdenum oxide layer may exhibit an amorphous phase immediately after deposition on the substrate, regardless of the presence or absence of the aforementioned metal nitride. After depositing the molybdenum oxide layer, heat treatment may induce changes in its oxidation state depending on the type of substrate material formed on the bottom of the molybdenum oxide layer. The oxidation state of the molybdenum oxide layer may also vary depending on the heat treatment temperature.

Herein, the heat treatment is preferably performed at a temperature ranging from 400° C. to 700° C. If the heat treatment temperature is less than 400° C., the formed molybdenum oxide may not be sufficiently converted into MoO₂. On the other hand, if the heat treatment temperature exceeds 700° C., the excessive heat may cause the molybdenum oxide layer to be excessively reduced, resulting in a large amount of conversion to metallic Mo rather than the desired oxidized form. More detailed information regarding this matter will be specifically described in the {Examples and Evaluation}section below.

Herein, the molybdenum oxide layer may be converted into molybdenum oxides with different oxidation numbers as a result of heat treatment on the substrate. Specifically, after deposition, the molybdenum oxide layer may be converted through heat treatment into different forms, such as MoO₃, Mo₄O₁₁, MoO₂, and fully reduced metallic Mo.

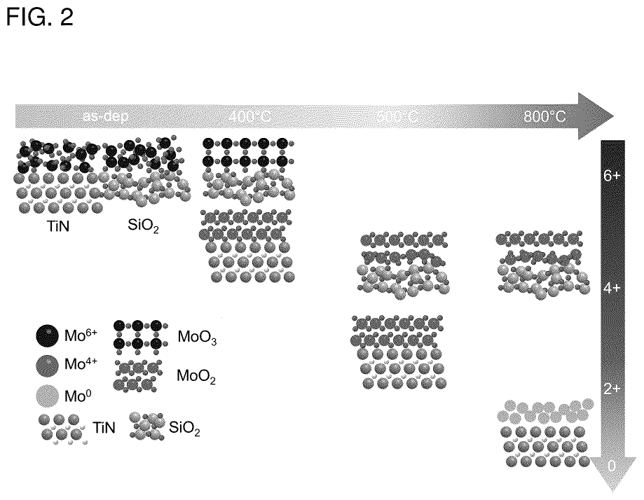

FIG. 2 is a schematic diagram illustrating oxidation states of molybdenum oxide based on the heat treatment temperature and type of substrate of a self-patterning electrode according to the present disclosure. The oxidation numbers of the molybdenum oxide were examined immediately after deposition (without heat treatment) and after heat treatment at 400° C., 500° C., and 800° C., respectively, on TiN and SiO₂ substrates.

Referring to FIG. 2, The mechanism by which the oxidation state and crystallization behavior of the molybdenum oxide (MoOₓ, where x=0 to 3) layer vary depending on the substrate can be explained as follows. In the as-deposited state, the MoOₓ thin films deposited using 03 as an oxidant can exhibit a predominant stoichiometry of MoO₃, irrespective of the substrate. This is evident because MoO₃ is thermodynamically stable, and Mo in Mo(CO)₆ already possesses a 6+ oxidation state. However, the reduction of MoOₓ during the heat treatment process (e.g., a post-deposition annealing (PDA) process) may be strongly influenced by the substrate chemistry. On a TiN substrate, the oxygen scavenging effect facilitates the reduction of MoOₓ, making it easier to form MoO₂ compared to in the case of a SiO₂ substrate. Moreover, a rutile-phase TiO₂ layer forms on the TiN surface, enabling the attainment of highly crystallized MoO₂, which can only be achieved when deposited on TiN. Consequently, it can be inferred that when a common deposition process is followed by a heat treatment process, conductive MoO₂ and insulating MoO₃ are separately formed on TiN and other substrates (e.g., SiO₂), respectively.

As described above, in the self-patterning electrode according to the present disclosure, MoO₂ may be formed in a portion of the substrate patterned with the metal nitride, while MoO₃ may be formed in a portion of the substrate not patterned with the metal nitride. MoO₂, as a conductive oxide, exhibits a relatively high work-function of 5.5 eV, making it suitable for use as an electrode material. In contrast, MoO₃ exhibits insulating properties.

In other words, the manufacturing method of the self-patterning electrode according to the present invention allows the conductive MoO₂ to be self-isolated (patterned) by the insulating MoO₃ without additional processes such as lithography, and since both the electrode and the insulating material can be patterned simultaneously, an effect of simplified processing can be expected.

Additionally, the present disclosure describes the self-patterning electrode manufactured through the method described above as a means to achieve the aforementioned objective.

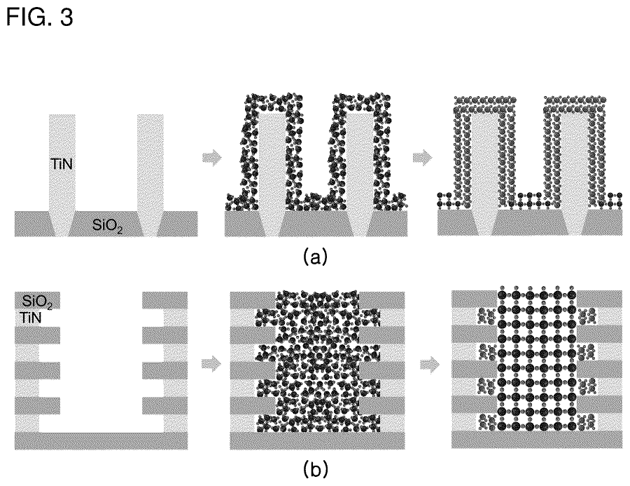

FIG. 3 is a schematic diagram illustrating a manufacturing process of a self-patterning electrode according to an example of the present disclosure. More specifically, (a) of FIG. 3 illustrates the process of patterning an electrode in a DRAM capacitor device, and (b) of FIG. 3 illustrates the process of patterning an electrode in a V-NAND flash memory device.

Referring to FIG. 3, it can be confirmed that a method for manufacturing a self-patterning electrode according to the present disclosure enables the easy patterning of electrode formation and isolation in vertical structures without requiring complex processes or additional technologies, even in electronic devices with various structures, as shown in (a) and (b) of FIG. 3.

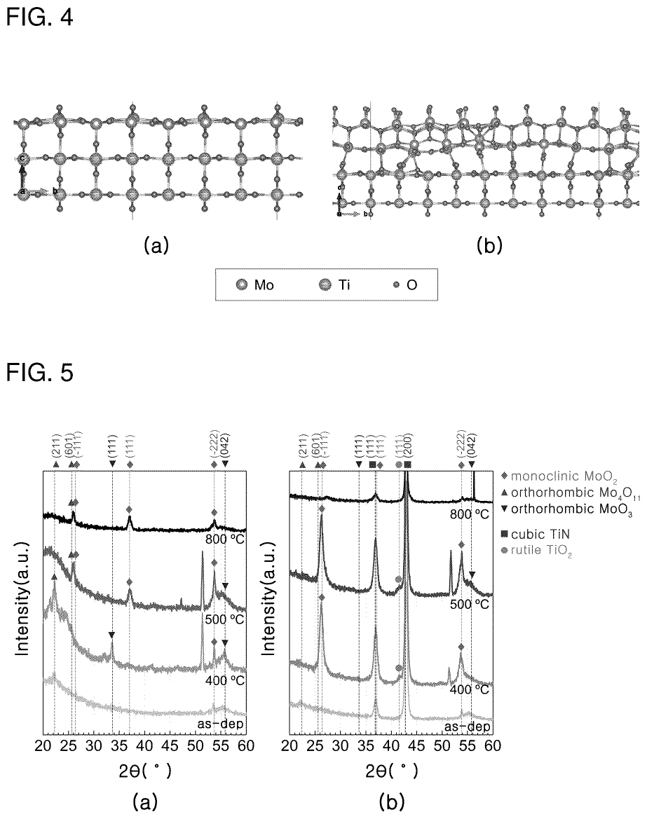

FIG. 4 is a schematic diagram illustrating the crystal structure of a self-patterning electrode according to the present disclosure. More specifically, (a) of FIG. 4 shows the crystal structure of MoO₂/rutile-TiO₂ (hereinafter referred to as “r-TiO₂”), and (b) of FIG. 4 shows the crystal structure of MoO₃/r-TiO₂.

Referring to FIG. 4, the respective crystal structures are described as follows. On the r-TiO₂ (110) surface, which has the lattice constants of a-, and c-axes of 2.963, and 6.594 Å, respectively, the MoO₂ (011) surface with the lattice constants of a-, and c-axes of 5.740, and 13.790 Å can form a heterostructure with supercells of MoO₂ (2×a_{MoO2}+2×c_{MoO2}) and r-TiO₂ (1×a_{r-TiO2}+1×c_{r-TiO2}) as shown in (a) of FIG. 3. The lattice mismatch between MoO₂ and r-TiO₂ crystal structure is 3.15% and −4.57% on a-, and c-axis, respectively. To investigate the thermodynamic stability of the MoO₂/r-TiO₂ interface, the formation energy (EF) per a unit cell of r-TiO₂ was calculated as follows: EF=(E_{MoO2/r-TiO2}−E_{MoO2}−E_{r-TiO2})/n_{r-TiO2}, where E_{MoO2/r-TiO2}, E_{MoO2} and E_{r-TiO2} are the total energy of the optimized MoO₂/r-TiO₂ heterostructure, MoO₂ (011) surface, and r-TiO₂ (110) surface, respectively. n_{r-TiO2} refers to the number of r-TiO₂ unit cells within the MoO₂/r-TiO₂ heterostructure. The calculated formation energy was −2.648 eV. Moreover, it can be confirmed that both MoO₂ and r-TiO₂ structures exhibited a stable structure with sustaining their own crystal structures. For a monolayer α-MoO₃ with lattice constants of a-, and c-axes of 3.923 Å and 3.696 Å, a MoO₃/r-TiO₂ heterostructure with supercells of monolayer MoO₃ (3×a_{MoO3}+7×C_{MoO3}) and r-TiO₂ (4×a_{r-TiO2}+4×c_{r-TiO2}) was constructed by minimizing the lattice mismatch between MoO₃ and r-TiO₂. In this case, lattice mismatch was 0.70% and 1.91% to a- and c-axis directions, respectively. However, the formation energy was −1.011 eV, indicating not favorable than interface formation with MoO₂. Moreover, referring to (b) of FIG. 3, it can be confirmed that the crystal structure of MoO₃ was severely deteriorated. Severe lattice distortion and bonding mismatch of the MoO₃ structure were induced to form a bonding structure on r-TiO₂ surface. In this regard, the different crystallization behavior of MoO₂ and MoO₃ on r-TiO₂ and SiO₂ surfaces is explained as follows. The MoOₓ thin film deposited on the SiO₂ substrate does not have any crystallization preferential because of amorphous crystal structure of the SiO₂. Therefore, the MoOₓ thin film has a mixture of various polymorphs of MoOₓ with relatively weak crystallinity. In contrary, on the TiN substrate, the crystal structure of r-TiO₂ formed on the TiN surface strongly governs the crystallization of MoOₓ thin film. Due to the similarity of crystal structure between MoO₂ and r-TiO₂, a region of MoO₂ in the MoOₓ thin film is facilely crystallized by the template effect of r-TiO₂. Additionally, calculations with a negative formation energy for MoO₂/r-TiO₂ suggest that MoO₂ is expected to be stable on r-TiO₂.

Hereinafter, the subject matter claimed in the present specification will be described in further detail with reference to the accompanying drawings and embodiments. However, the drawings and embodiments presented in the present specification may be modified in various ways by those skilled in the art and may take various forms. Accordingly, the descriptions in the present invention should not be construed as being limited to specific disclosed forms but should be understood to include all equivalents or substitutes that fall within the spirit and scope of the present invention. Furthermore, the accompanying drawings are provided to enable those skilled in the art to more accurately understand the present invention and may be depicted in an exaggerated or reduced manner relative to actual proportions.

### EXAMPLES AND EVALUATION

### Examples

The substrate consisted of 50 nm-thick TiN (deposited by a chemical vapor deposition process) as a bottom electrode (BE) on a SiO₂ (100) wafer. As a Mo precursor, Mo(CO)₆ was placed into a canister and heated to 50° C. to generate sufficient vapor pressure. The concentration of O₃ was maintained at 200 g/m³. The ALD sequence was consisted of Mo(CO)₆ feeding, Ar purge, O₃ feeding, and Ar purge of 7, 10, 3, and 10 seconds, respectively. A MoOₓ layer was deposited on the substrate to a thickness of either 5 nm or 15 nm. The deposited MoOₓ thin films were annealed (post-deposition annealing, PDA) for 30 seconds under N₂ atmosphere (99.999%) at 400° C., 500° C. and 800° C. by a rapid thermal annealing system (MIRA-5050, ULVAC).

### Evaluation

FIG. 5 is an XRD spectrum of the self-patterning electrode manufactured according to an example of the present disclosure. More specifically, (a) of FIG. 5 illustrates the XRD spectra of MoOₓ deposited on an SiO₂ substrate followed by heat treatment at different temperatures, while (b) of FIG. 5 illustrates the XRD spectra of MoOₓ deposited on a TiN substrate followed by heat treatment at different temperatures.

Referring to FIG. 5, it can be confirmed that, MoOₓ deposited on both TiN and SiO₂ substrates remains in an amorphous phase in the as-deposited state. However, the PDA process induced a significant difference in the crystallinity of the MoOₓ thin films deposited on TiN and SiO₂ substrates. It can be confirmed that, in the case of MOOₓ/SiO₂, the diffraction peaks indicate that the crystalline structure of the MoOₓ thin film consists of various polymorphs of MoOₓ, which change depending on the PDA temperature. Specifically, it can be confirmed that, after PDA at 400° C. (PDA400), diffraction peaks corresponding to Mo₄O₁₁ and MoO₃ were observed. It also can be confirmed that, as the PDA temperature increased, the diffraction peaks corresponding to MoO₃ decreased, while those corresponding to MoO₂, which has a lower oxidation state, gradually appeared. However, the phase change and crystallization behaviors of MoOₓ deposited on the TiN substrate were different from that of SiO₂ substrate. It can be confirmed that, the MoOₓ thin film deposited on TiN and conducting the PDA process at 400° C. had a single-phased crystal structure of the monoclinic MoO₂. Additionally, it can be confirmed that, compared to the XRD plot of the SiO₂ substrate, the intensity and peak shape were significantly high and sharp. Moreover, as the PDA temperature increased, intensity of a diffraction peak at 56° corresponding to MoO₃ was increased. At a PDA temperature of 800° C., diffraction peaks corresponding to MoO₂ were almost disappeared. Since the MoOₓ thin film has various oxidation states of Mo ion (i.e., Mo⁴⁺, Mo⁵⁺, and Mo⁶⁺) and its own crystal structures, it is challenging to obtain a single-phase MoOₓ thin film. Indeed, MoOₓ/SiO₂ exhibited a mixed crystal structure with varied oxidation states of 2≤x≤3. Moreover, its crystallinity (related with intensity of diffraction peak) was quite low considering its film thickness of 10 nm. However, MoOₓ/TiN exhibited very strong and sharp diffraction peaks corresponding to only the crystal structure of MoO₂, indicating that the MoOₓ/TiN thin film consisted of solely MoO₂ crystal structure with a remarkable high crystallinity.

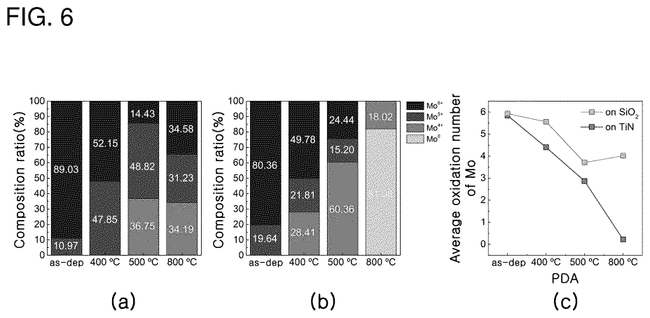

FIG. 6 is a graph illustrating the composition ratio of molybdenum ion oxidation states according to the heat treatment temperature and type of substrate of a self-patterning electrode manufactured according to an example of the present disclosure. More specifically, (a) of FIG. 6 illustrates the composition ratio of the molybdenum oxidation states in the MoOₓ layer formed on an SiO₂ substrate, and (b) of FIG. 6 illustrates the composition ratio of the molybdenum oxidation states in the MoOₓ layer formed on a TiN substrate. (c) of FIG. 6 illustrates the average oxidation number of Mo in MoOₓ layers. The oxidation state of the MoOₓ thin film was investigated by the XPS analyses.

Referring to FIG. 6, it can be confirmed that MoOₓ/SiO₂ and MoOₓ/TiN thin films had almost identical chemical state at the as-deposited state; mostly Mo⁶⁺ oxidation state due to high oxidation potential of O₃. The average oxidation numbers of MoOx/SiO₂ and MoOₓ/TiN at the as-deposited state were 5.93 and 5.83, respectively. This result was coincided with the XRD result in FIG. 5, implying no differences in the physical and chemical states between both MoOₓ/SiO₂ and MoOₓ/TiN at the as-deposited state. In other words, it can be seen that the MoOₓ deposition behavior during the ALD process was not influenced by the substrate. Moreover, it can be confirmed that a changing in the oxidation state depending on the PDA temperature was also analogous in both MoOₓ/SiO₂ and MoOₓ/TiN; as increasing the PDA temperature, Mo cation in MoOₓ thin film being more reduced. However, it can be confirmed that only the trend was similar, the level of reduction was different regarding the substrate. In the case of the MoOₓ/SiO₂ thin film, the reduction to Mo⁴⁺ was obtained in the PDA at 500° C. (PDA500), and no further reduction was occurred in further PDA temperature increasing to 800° C. (PDA800). However, in the MoOₓ/TiN thin film, a significant formation of Mo⁴⁺ reduction state was observed at the PDA at 400° C. (PDA400), and the Mo cation in MoOₓ thin film was reduced consistently with increasing the PDA temperature. Eventually, it can be confirmed that Mo metal phase of composition ratio of 82% with an average oxidation number of Mo of 0.22 was obtained at the PDA800. This indicates that an exceptionally severe reduction of the MoOₓ thin film occurred only on TiN substrate during the PDA, not occurred on SiO₂. This difference in the reduction of MoOₓ by the PDA depending on the substrate was originated from the oxidation potential difference between TiN and SiO₂ substrate. While the SiO₂ could not induce the reduction from further oxidation of SiO₂, the TiN substrate could be oxidized to TiON and TiO₂ itself, inducing reduction of thin film deposited onto the TiN substrate, which is called the “oxygen scavenging effect”. The MoOₓ thin film intrinsically easy to reduce by thermal energy due to its relatively week binding energy of Mo—O. Therefore, the MoOx/SiO₂ thin film reduced to the average oxidation number from 5.93 to 3.71, but it exhibited a saturation behavior of that did not further reduce at PDA800 at the average oxidation number of 4.02. However, in the case of MoOₓ/TiN thin film, the oxygen scavenging effect of TiN facilitates the reduction of MoOₓ, in turn, the MoOₓ/TiN had much lower average oxidation number after conducting the PDA than that of the MoOx/SiO₂. Indeed, the formation of oxidized TiN, r-TiO₂ in this case, by the oxygen scavenging from MoOₓ thin film was observed in the XRD pattern in FIG. 5 at the PDA400 and PDA500.

However, the high and single-phased MoO₂ crystallization of MoOₓ/TiN at the PDA400 and PDA500 were not explained with the oxygen scavenging effect of TiN. It can be confirmed that, even though the MoOₓ/TiN thin film after conducting the PDA400 had high Mo⁶⁺ and Mo⁵⁺ composition ratio of 49.78% and 21.81%, respectively, only the MoO₂ phase of the composition ratio of 28.41% was crystallized. Moreover, it can be confirmed that, the PDA400 was sufficiently high temperature for inducing crystallization of MoO₃ as shown in the case of MoOₓ/SiO₂ thin film, hence, it can be inferred that, the thermal energy difference for the crystallization depending on the oxidation state, i.e., MoO₃ requires higher thermal budget to crystallization than that of MoO₂, was not the reason why only MoO₂ was crystallized in the MoOₓ/TiN thin film. As described in FIG. 4, the EF difference of MoO₂ and MoO₃ on r-TiO₂ is attributed to not only the selective crystallization facilitation of MoO₂, but also suppressing the crystallization of MoO₃, on TiN substrate.

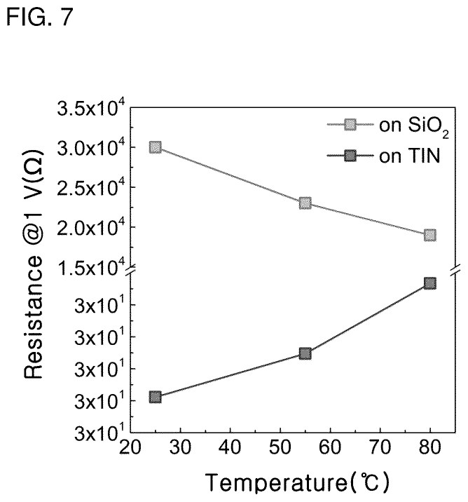

FIG. 7 is a graph illustrating the resistance of a self-isolating electrode manufactured according to an example of the present disclosure. FIG. 7 illustrates the results of resistance measurements, which were calculated from the current values at an applied voltage of +1 V for the MoOₓ/SiO₂ and MoOₓ/TiN electrodes, respectively, in the temperature range of 25° C. to 80° C. Each of the electrodes underwent PDA400. To mitigate interference with the current flow through the TiN bottom electrode beneath the MoOₓ/TiN thin film, additional TiO₂ and MoO₂ layers were deposited on the MoOₓ/TiN stack. The deposited TiO₂ thin film exhibited a rutile-phase crystal structure due to the presence of MoOₓ/TiN.

Referring to FIG. 7, the MoOₓ/SiO₂ thin film exhibited over 10⁴Ω and gradually decreased resistance with increasing the measurement temperature, implying that the MoO₃ component in the MoOₓ/SiO₂ thin film governs the resistance property of the thin film of insulator. However, the MoOₓ/TiN thin film had lower resistance values than that of MoOx/SiO₂, and it can be confirmed that the resistance values increased as the the measurement temperature increased. In other words, in can be inferred that the MoOₓ/TiN exhibited metallic resistance property. Even though the MoOₓ/TiN had only MoO₂ composition of 28.41%, highly crystallized MoO₂ may have induced the resistance property of whole MoOₓ/TiN thin film by its conductive oxide nature. Furthermore, it can be confirmed that the MoOₓ thin film showed an explicit contrast in its resistance depending on the substrate, even though performing exactly same deposition and PDA process.

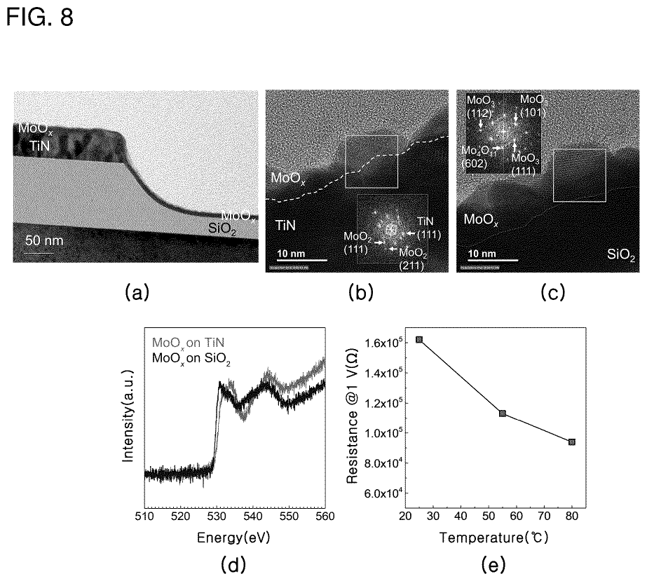

FIG. 8 illustrates HR-TEM images, fast-Fourier-transform (FFT) images, electron energy loss spectroscopy (EELS) analyses, and a resistance graph of a self-patterning electrode manufactured according to an example of the present disclosure. More specifically, (a) of FIG. 8 is a TEM image capturing the cross-section of a self-patterned electrode. (b) of FIG. 8 is an HR-TEM image and an FFT image of the MoOₓ/TiN electrode. (c) of FIG. 8 is an HR-TEM image and an FFT image of the MoOₓ/SiO₂ electrode. (d) of FIG. 8 illustrates the EELS spectra of the MoOₓ/TiN electrode and the MoOₓ/SiO₂ electrode. (e) of FIG. 8 presents the resistance measurement between two adjacent TiN pads.

Referring first to (a) of FIG. 8, it can be confirmed that the MoOₓ thin film is conformally deposited on both the TiN and SiO₂ surfaces, simultaneously. That is, it is confirmed that the MoOₓ/TiN and MoOₓ/SiO₂ thin films are formed separately in a same deposition and post-deposition annealing (PDA) process. Furthermore, (b) and (c) of FIG. 8 illustrate the results of an investigation into the crystallinity of the MoOₓ thin film using FFT patterns. Referring to (b) of FIG. 8, it is confirmed that the FFT pattern obtained from MoOₓ/TiN exhibits only the diffraction dots originated from MoO₂ and TiN crystal structures. In contrast, referring to (c) of FIG. 8, it can be confirmed that, in the case of MoOₓ/SiO₂, the FFT pattern consists of diffraction dots corresponding to the Mo₄O₁₁ and MoO₃ crystal structures. Meanwhile, referring to FIG. (d) of 8, the EELS spectrum of MoOₓ/TiN exhibits relatively higher energy than that of of MoOₓ/SiO₂, indicating that MoOₓ/TiN has a relatively lower oxidation state than that of MoOₓ/SiO₂. This implies that the oxygen scavenging effect of TiN also contributes to inducing the oxidation state difference in the patterned structure. Finally, referring to (e) of FIG. 8, it can be confirmed that the resistance at a measurement temperature of 25° C. is 1.62×10⁵Ω and gradually decreases as the measurement temperature increases. Consequently, on the patterned structure, the MoO₂ electrodes deposited on TiN were isolated each other by the simultaneously formed MoO₃ insulator deposited on SiO₂; the MoO₂ electrodes were “self-isolated”. That is, the method for manufacturing the self-patterned electrode according to the present invention enables the formation of a MoO₂ electrode on TiN while being simultaneously separated by MoO₂, without requiring any additional patterning or surface treatment processes. This suggests that the process allows for the ‘self-isolated electrode formation’.

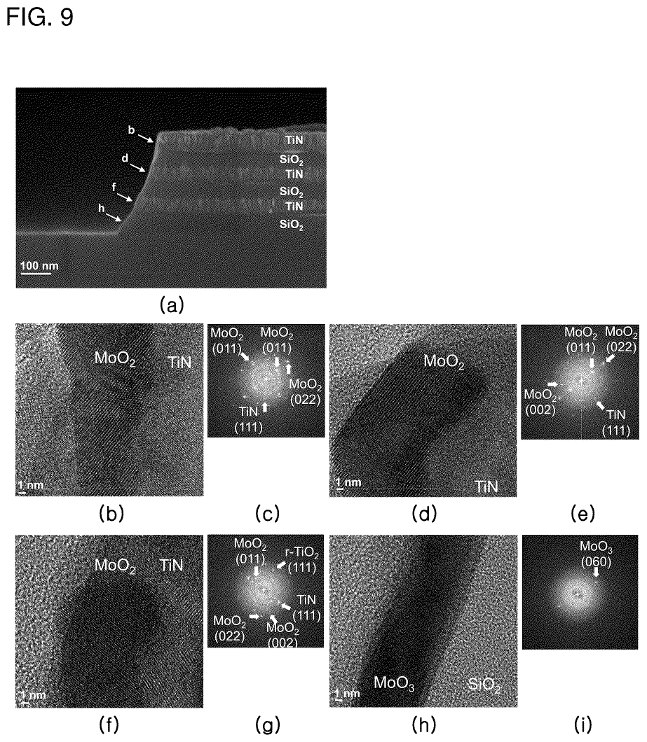

FIG. 9 illustrates HR-TEM images of a self-patterning electrode manufactured according to an example of the present disclosure. (a) of FIG. 9 is an SEM image capturing the cross-section of an electrode in which MoOₓ is formed on a substrate having TiN and SiO₂ alternately stacked in a vertical structure. (b) to (i) of FIG. 9 illustrate HR-TEM images and FFT images corresponding to each section indicated in (a) of FIG. 9. The electrode was manufactured by depositing a MoOₓ thin film with a thickness of 5 nm on TiN and SiO₂ layers having thicknesses of 50 nm, followed by performing PDA400.

Referring to FIG. 9, the HR-TEM images and their corresponding FFT patterns reveal that different crystal structured thin films, MoO₂ and MoO₃ onto TiN and SiO₂, respectively, are formed without any surface treatment or additional process. Furthermore, it is confirmed that in every TiN layer on the vertical structure, highly crystallized MoO₂ formations have been observed. In contrary, only MoO₃ crystal structure has been observed in the MoOₓ thin film deposited on the vertical SiO₂ surface. Therefore, the self-isolation electrode formation, MoO₂ electrode formation on TiN and isolated by MoO₃ formed on SiO₂ without any patterning process, has been successfully demonstrated on the vertical structure. It is confirmed that since the crystallization of MoO₂ is attributed to the template effect induced by r-TiO₂ formed on the surface of TiN, the driving force for crystallization decreases with increasing thickness of the MoOₓ/TiN thin film. Consequently, as the film thickness increases, the reduction of Mo slightly diminishes, and a MoO₃ diffraction peak was observed at relatively thick thicknesses of 10 nm.

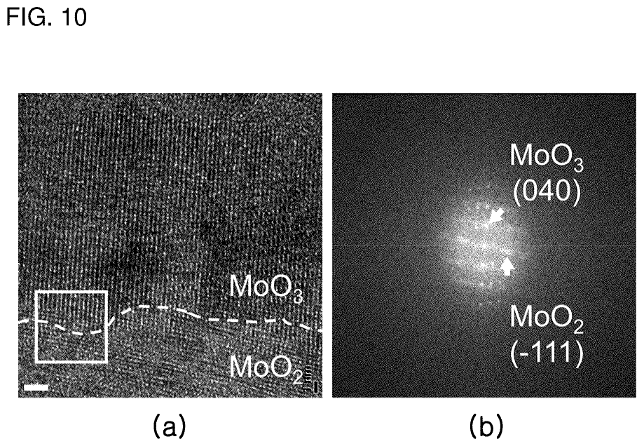

FIG. 10 illustrates an HR-TEM image and an FFT image of a self-patterning electrode manufactured according to an example of the present invention. More specifically, (a) of FIG. 10 is an HR-TEM image of an electrode in which MoOₓ is deposited to a thickness of 15 nm on a TiN substrate, and (b) of FIG. 10 is an FFT image of an electrode in which MoOₓ is deposited to a thickness of 15 nm on a TiN substrate. The electrode shown in FIG. 10 was manufactured through a PDA400 process.

Referring to FIG. 10, it can be confirmed that the transition of the crystal structure from MoO₂ to MoO₃ according to thickness is distinctly observed. This result suggests that the reduction of the template effect induces a specific thickness of the MoO₂ electrode structure while simultaneously allowing capping with isolated MoO₃. That is, due to the template effect, the formation of MoO₂ on TiN induces the formation of insulating MoO₃ on MoO₂ when the film thickness exceeds a certain threshold.

The manufacturing method of the self-patterning electrode of the present disclosure enables the easy formation of conductive MoO₂ and insulating MoO₃ in an isolated manner without requiring complex processes such as exposure and etching.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A method for manufacturing a self-patterning electrode comprising:
preparing a substrate patterned with a metal nitride;
forming a molybdenum oxide layer on the patterned substrate; and
heat treating the substrate on which the molybdenum oxide layer is formed.

2. The method of claim 1,
wherein the metal nitride exhibits, upon oxidation, a rutile crystal phase.

3. The method of claim 1,
wherein the metal nitride includes one or more substances selected from a group consisting of TiN, SnN and RuN.

4. The method of claim 1,
wherein the molybdenum oxide layer is formed using a molybdenum precursor and an oxidant.

5. The method of claim 4,
wherein the molybdenum precursor is one or more substances selected from a group consisting of Mo(CO)₆, MoO₂Cl₂, MoF₆, (tBuN)₂Mo(NMe₂)₂, and (tBuN)₂Mo(Net₂)₂.

6. The method of claim 4,
wherein the oxidant is one or more selected from a group consisting of O₃, H₂O, and O₂ plasmas.

7. The method of claim 1,
wherein the heat treatment is performed at a temperature ranging from 400 to 700° C.

8. The method of claim 1,
wherein the molybdenum oxide layer is converted into molybdenum oxides having different oxidation states as heat treatment is performed on the substrate.

9. The method of claim 1,
Wherein, in portions of the substrate patterned with the metal nitride, MoO₂ is formed, and in portions of the substrate not patterned with the metal nitride, MoO₃ is formed.

10. A self-patterning electrode manufactured by the method according to claim 1.
